(19) United States
(12) Patent Application Publication
(10) Pub. No.: US 2007/0061659 A1
(43) Pub. Date: Mar. 15, 2007

(54) Methods for testing a plurality of semiconductor devices in parallel and related apparatus

(75) Inventors: Byong-Hui Yun, Gyeonggi-do (KR); Ki-Myung Seo, Gyeonggi-do (KR); Do-Hoon Byun, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/435,499

(22) Filed: May 17, 2006

(30) Foreign Application Priority Data
Aug. 18, 2005 (KR) 10-2005-0075505

(51) Int. Cl. G01R 31/28; G06F 11/00

(52) U.S. Cl. 714/742

(57) ABSTRACT

A method for testing a semiconductor device includes generating chip identification data for each of a plurality of devices under test to collect a plurality of chip identification data respectively corresponding to the plurality of devices under test. The plurality of chip identification data for the plurality of devices under test is transmitted responsive to collection thereof. The plurality of chip identification data may be received and written in parallel to the corresponding ones of the plurality of devices under test. Related apparatus are also discussed.

### CROSS-REFERENCE TO RELATED PATENT APPLICATIONS

This application claims priority from Korean Patent Application No. 10-2005-0075505, filed on Aug. 18, 2005, in the Korean Intellectual Property Office, the disclosure of which is incorporated herein by reference in its entirety.

### FIELD OF THE INVENTION

The present invention relates to semiconductor devices, and more particularly, to apparatus and methods for testing semiconductor devices.

### BACKGROUND OF THE INVENTION

An electrical die sorting (EDS) test is a process in which bad wafers are sorted out by checking the electrical operation of chips on a wafer using a tester and a wafer probe. More particularly, an input pattern may be written to a chip on a wafer using the tester, and the written pattern may be read to compare it with a reference value to determine whether the chip is good or whether the chip fails.

The tester may write chip identification data (including, for example, a lot number, a wafer number, a product name, and/or device under test (DUT) coordinates on a wafer) and a logic signal pattern (regarding the operation of a chip) to each chip (i.e., device under test (DUT)), on the wafer, and may check a logic signal pattern output from an output terminal of each chip. During a test, the tester may sequentially write a test pattern and different chip identification data to the DUTs while updating the chip identification data.

FIG. 1 is a diagram illustrating a conventional data writing method. Referring to FIG. 1, when there are 64 DUTs, data may be sequentially written to the 64 DUTs starting from DUT #1 at the left upper corner of the diagram, and continuing downward to the remaining DUTs and starting again from a DUT to the right of the DUT #1. As such, a time required to write data to all of the 64 DUTs may be 64 times greater than that required to write data to one DUT. Accordingly, the time required to write data to all of the DUTs may be increased in proportion to the total number of DUTs, thereby increasing a test duration.

### SUMMARY OF THE INVENTION

Some embodiments of the present invention may provide a data writing apparatus and method, in which chip identification data and a test pattern for all devices under test (DUTs) may be generated and dumped to a tester, so that they can be written in parallel to the DUTs.

According to some embodiments of the present invention, an apparatus for writing an input pattern for a test and chip identification data to a plurality of devices under test (where the chip identification data may identify the devices under test) may include a host computer that may be configured to generate and dump the input pattern and the chip identification data for each of the devices under test; and a tester that may be configured to store the input data and the chip identification data, transform the input pattern into a logic signal pattern, and write the logic signal pattern and the chip identification data in parallel to the devices under test.

According to other embodiments of the present invention, a method of writing an input pattern for a test and chip identification data to a plurality of devices under test (where the chip identification data may identify the devices under test) may include a host computer generating and dumping the input pattern and the chip identification data, a tester separately storing the dumped input pattern and chip identification data for each of the devices under test in a storage unit, the tester reading the input patter and the chip identification data in parallel from the storage unit, and the tester transforming the input pattern into a logic signal pattern, and writing the logic signal pattern and the chip identification data in parallel to the respective devices under test.

According to still other embodiments of the present invention, a data writing apparatus for an electrical die sorting test may include a device interface unit, a storage unit, and a writing unit. The device interface unit may be configured to connect a plurality of devices under test at a same time. The storage unit may be configured to receive an input pattern and chip identification data dumped from the host computer, and may be configured to separately store the input pattern and the chip identification data for each of the devices under test, where the input pattern may be used to test the devices under test, and where the chip identification data may be used to identify the devices under test. The writing unit may be configured to transform the input pattern into a logic signal pattern, and write the logic signal pattern and the chip identification data in parallel to the devices under test via the device interface unit.

According to some embodiments of the present invention, a method for testing a semiconductor device may include generating chip identification data for each of a plurality of devices under test to collect a plurality of chip identification data respectively corresponding to the plurality of devices under test. The plurality of chip identification data for the plurality of devices under test may be transmitted responsive to collection of the plurality of chip identification data. For example, the plurality of chip identification data may be transmitted simultaneously and/or in parallel.

In some embodiments, transmitting the plurality of chip identification data may include writing the plurality of chip identification data to corresponding ones of the plurality of devices under test in parallel.

In other embodiments, test pattern data may be generated for the plurality of devices under test, and the test pattern data and the plurality of chip identification data may be transmitted responsive to collection thereof. For example, the test pattern data may be generated based on particular characteristics of the plurality of devices under test.

According to other embodiments of the present invention, a method for testing a plurality of semiconductor devices may include receiving a plurality of chip identification data respectively corresponding to a plurality of devices under test. For example, the plurality of chip identification data may be received simultaneously and/or in parallel. The plurality of chip identification data may be written to corresponding ones of the plurality of devices under test in parallel.

In some embodiments, the plurality of chip identification data may be read in parallel prior to writing the plurality of chip identification data.

In other embodiments, test pattern data may also be written to the plurality of devices under test in parallel along with the plurality of chip identification data. For example, prior to writing the test pattern data, input signal pattern data may be received for the plurality of devices under test, and the input signal pattern data may be transformed into logical signal pattern data. The logical signal pattern data and the chip identification data may be written to the plurality of devices under test in parallel.

In some embodiments, prior to receiving the plurality of chip identification data, chip identification data may be sequentially generated for each of the plurality of devices under test to collect the plurality of chip identification data. The plurality of chip identification data may be transmitted responsive to collection of the chip identification data for each of the plurality of devices under test.

According to further embodiments of the present invention, an apparatus for testing a plurality of semiconductor devices may include a controller and a writing unit coupled to the controller. The controller may be configured to receive a plurality of chip identification data respectively corresponding to a plurality of devices under test. For example, the controller may be configured to receive the plurality of chip identification data simultaneously and/or in parallel. The writing unit may be configured to write the plurality of chip identification data to corresponding ones of the plurality of devices under test in parallel.

In some embodiments, the writing unit may be further configured to read the plurality of chip identification data in parallel responsive to receipt thereof by the controller.

In other embodiments, the apparatus may include an interface unit configured to provide a parallel connection between the writing unit and the plurality of devices under test.

In other embodiments, the writing unit may be configured to receive input signal pattern data for the plurality of devices under test from the controller, transform the input signal pattern data into logical signal pattern data, and write the logical signal pattern data to the plurality of devices under test in parallel.

In some embodiments, the apparatus may include a programming unit configured to generate chip identification data for each of a plurality of devices under test. The programming unit may be further configured to collect the chip identification data to provide the plurality of chip identification data respectively corresponding to the plurality of devices under test, and transmit the plurality of chip identification data for the plurality of devices under test to the controller responsive to collection of the plurality of chip identification data.

In other embodiments, the programming unit may be configured to generate test pattern data for the plurality of devices under test. The programming unit may be further configured to transmit the test pattern data and the plurality of chip identification data responsive to collection thereof. The writing unit may be further configured to write the test pattern data to the plurality of devices under test in parallel.

According to still further embodiments of the present invention, an apparatus for testing a semiconductor device may include a programming unit configured to generate chip identification data for each of a plurality of devices under test. The programming unit may be further configured to collect the chip identification data to provide a plurality of chip identification data respectively corresponding to the plurality of devices under test, and to transmit the plurality of chip identification data for the plurality of devices under test responsive to collection thereof.

In some embodiments, the apparatus may further include a writing unit coupled to the programming unit. The writing unit may be configured to receive the plurality of chip identification data from the programming unit, and write the plurality of chip identification data to corresponding ones of the plurality of devices under test in parallel.

### BRIEF DESCRIPTION OF THE DRAWINGS

FIG. 1 is a diagram illustrating a conventional data writing method;

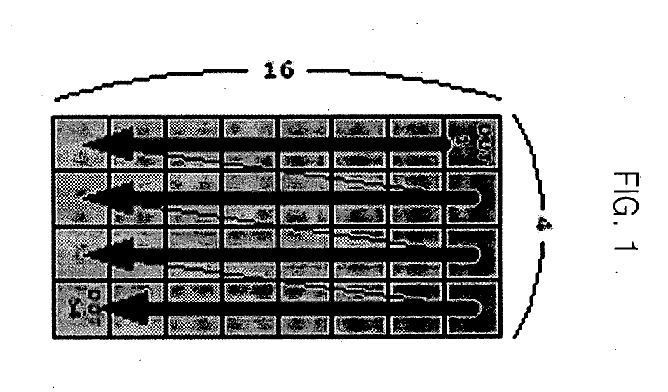

FIG. 2 illustrates an apparatus for writing test data to semiconductor devices according to some embodiments of the present invention;

FIG. 3 is a block diagram illustrating a host computer and a tester as shown in FIG. 2; and

FIG. 4 is a flowchart illustrating methods of writing data to semiconductor. devices according to some embodiments of the present invention.

### DETAILED DESCRIPTION OF EMBODIMENTS OF THE INVENTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout. It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

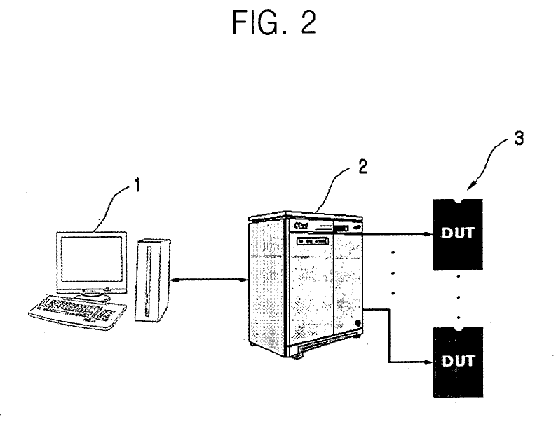

FIG. 2 illustrates an apparatus for writing test data to semiconductor devices according to some embodiments of the present invention. Referring now to FIG. 2, the apparatus includes a host computer 1 and a tester 2. Reference numeral 3 denotes a plurality of devices under test (DUTs) to which data is to be written.

The host computer 1 generates an input pattern and chip identification data for each of the DUTs 3, collects chip identification data for all of the DUTs 3, and “dumps” the input pattern and the chip identification data to the tester 2. In other words, after collecting the chip identification data for all of the DUTs 3, the host computer 1 simultaneously transmits the input pattern and the chip identification data for all of the DUTs 3 to the tester 2. The tester 2 stores the input pattern and the chip identification data of the DUTs 3, transforms the input pattern into a logic signal pattern that is at a logic high/low level, and writes the logic signal pattern and the chip identification data in parallel to the DUTs 3.

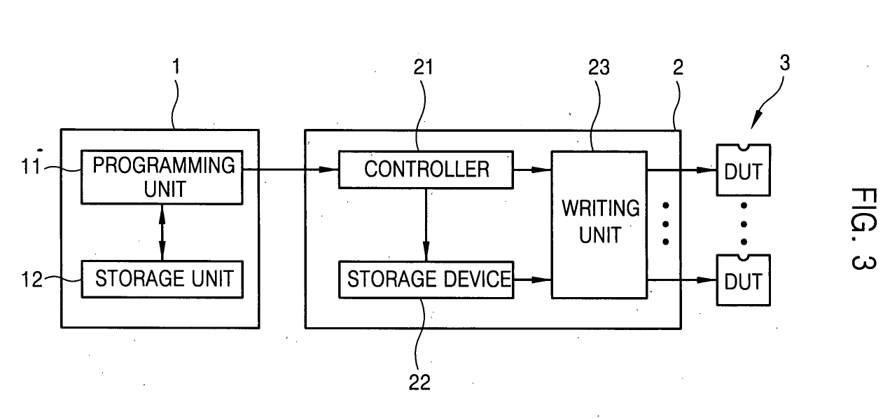

FIG. 3 is a block diagram illustrating the host computer 1 and the tester 2 of FIG. 2, according to some embodiments of the present invention. Reference numeral 3 denotes a plurality of DUTs. The host computer 1 includes a programming unit 11 and a storage unit 2.

The programming unit 11 generates an input pattern and chip identification data for the respective DUTs 3, which are to be written to the DUTs 3, and stores them in the storage unit 12. The input pattern is applied to all of the DUTs 3, and thus, is determined by the particular characteristics of the DUTs 3. As described above, the chip identification data specifies a lot number, a wafer number, a product name, DUT coordinates on a wafer, etc., and as such, may be different for each of the DUTs 3.

After the input pattern and the chip identification data for all of the DUTs 3 are stored in the storage unit 12, the programming unit 11 “dumps” (i.e., simultaneously transmits) the stored input pattern and the chip identification data for all the DUTs to the tester 2. The tester 2 includes a controller 21, a storage device 22, and a writing unit 23. The writing unit 23 may be connected to a device interface unit (not shown) that provides an interface between the writing unit 23 and the DUTs 3.

The controller 21 stores the dumped input pattern and chip identification data for all of the DUTs 3 in the storage device 22. The storage device 22 may include a plurality of storage units that store the input pattern and the chip identification data for all of the corresponding DUTs 3.

The writing unit 23 transforms the input pattern into a logic signal pattern, inputs it to a pin of each of the DUTs 3, and writes the chip identification data to a designated region of corresponding ones of the DUTs 3. More particularly, a pin number of each DUT 3 to which the input pattern is input and the region of each DUT 3 in which the chip identification data is stored may be determined by and transmitted from the programming unit 11.

The writing unit 23 reads the input pattern and chip identification data to be written to the DUTs 3 in parallel from the storage device 22 in response to a first control signal output from the controller 21, transforms the input pattern into a logic signal pattern in response to a second control signal output from the controller 21, and writes the logic signal pattern and the chip identification data for all of the DUTs 3 in parallel to corresponding ones of the DUTs 3. The input pattern and the chip identification data may be written through a device interface unit (not shown) that provides an interface between the writing unit 23 and the DUTs 3.

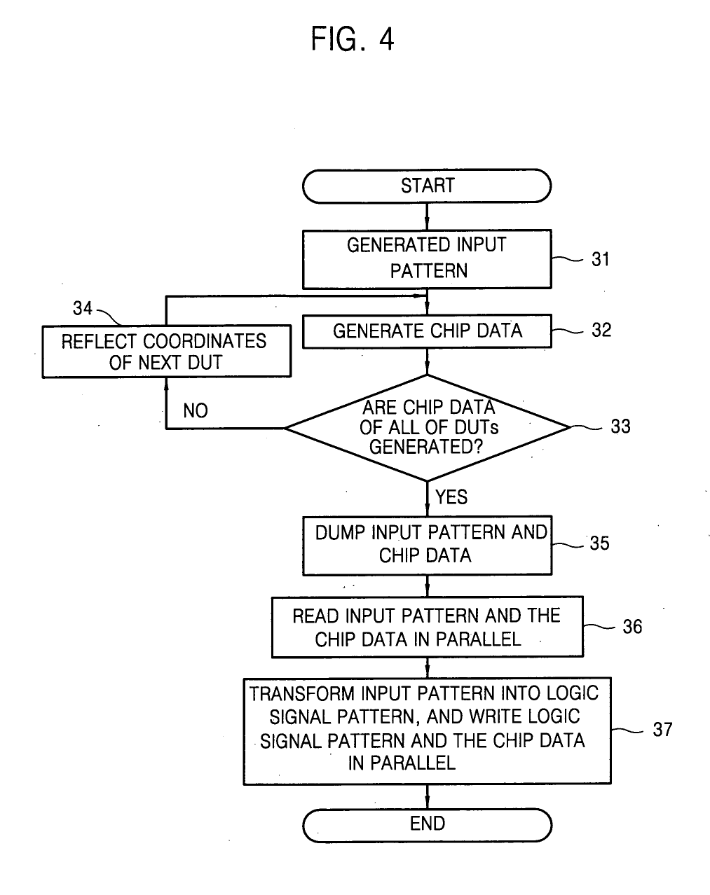

FIG. 4 is a flowchart illustrating methods of writing test data to semiconductor devices according to some embodiments of the present invention. Referring now to FIG. 4, the programming unit 11 of the host computer 1 of FIG. 2 generates an input pattern according to the characteristics of the DUTs 3 (Block 31). Then, the programming unit 11 generates chip identification data (specifying a lot number, a wafer number, a product name, DUT coordinates on a wafer, etc) for each of the DUTs 3 (Block 32). Next, it is determined whether the chip identification data for all of the DUTs 3 has been generated (Block 33). If it is determined at Block 33 that the chip identification data for all of the DUTs 3 has not been generated, chip identification data is generated to reflect the coordinates of a next DUT on the wafer (Block 34). If it is determined at Block 33 that the chip identification data of all of DUTs 3 has been generated, the generated input pattern and chip identification data are dumped to the controller 21 of the tester 2 (Block 35).

The controller 21 separately stores the input pattern and the chip identification data for each of the DUTs 3 in the storage device 22. The writing unit 23 reads the input pattern and the chip identification data for all of the DUTs in parallel from the storage device 22 (Block 36). The writing unit 23 transforms the input pattern into a logic signal pattern, and writes the logic signal pattern and the chip identification data for all of the DUTs in parallel to the corresponding ones of the DUTs 3 (Block 37).

Thus, according to some embodiments of the present invention, in an electrical die sorting (EDS) test, a pattern and chip identification data to be tested are output in parallel to be simultaneously written to a plurality of DUTs, thereby reducing the time required to write the pattern and chip identification data and the test duration. Also, the results of testing all of DUTs can be simultaneously checked, thereby increasing user convenience.

While the present invention has been particularly shown and described with reference to exemplary embodiments thereof, it will be understood by those skilled in the art that various changes in form and details may be made therein without departing from the spirit and scope of the invention as defined by the appended claims.

That which is claimed:

1. An apparatus for writing an input pattern for a test and chip identification data to a plurality of devices under test, the chip identification data identifying the devices under test, the apparatus comprising:
a host computer generating and dumping the input pattern and the chip identification data; and
a tester storing the input data and the chip identification data, transforming the input pattern into a logic signal pattern, and writing the logic signal pattern and the chip identification data in parallel to the device under test.

2. The apparatus of claim 1, wherein the tester comprises:
a storage unit storing the input pattern and the chip identification data;
a controller separately storing the input pattern and the chip identification data for each of the devices under test in the storage unit, and outputting a first control signal and a second control signal; and
a writing unit reading the input pattern and the chip identification data in parallel from the storage unit in response to the first control signal, transforming the input pattern into the logic signal pattern in response to the second control signal, and writing the logic signal pattern and the chip identification data in parallel to the devices under test.

3. A method of writing an input pattern for a test and chip identification data to a plurality of devices under test, the chip identification data identifying the devices under test, the method comprising:
a host computer generating and dumping the input pattern and the chip identification data;
a tester separately storing the dumped input pattern and chip identification data for each of the devices under test in a storage unit;
the tester reading the input pattern and the chip identification data in parallel from the storage unit; and
the tester transforming the input pattern into a logic signal pattern, and writing the logic signal pattern and the chip identification data in parallel to the respective devices under test.

4. A data writing apparatus for an electrical die sorting test, the apparatus comprising:
a device interface unit connecting a plurality of devices under test at a time;
a storage unit receiving an input pattern and chip identification data dumped from the host computer, and separately storing the input pattern and the chip identification data for each of the devices under test, the input pattern being used to test the devices under test, the chip identification data identifying the devices under test; and
a writing unit transforming the input pattern into a logic signal pattern, and writing the logic signal pattern and the chip identification data in parallel to the devices under test via the device interface unit.

5. A method for testing a semiconductor device, the method comprising:
generating chip identification data for each of a plurality of devices under test to collect a plurality of chip identification data respectively corresponding to the plurality of devices under test; and
transmitting the plurality of chip identification data for the plurality of devices under test responsive to collection of the plurality of chip identification data.

6. The method of claim 5, wherein transmitting the plurality of chip identification data comprises:
writing the plurality of chip identification data to corresponding ones of the plurality of devices under test in parallel.

7. The method of claim 5, further comprising:
generating test pattern data for the plurality of devices under test,
wherein transmitting further comprises transmitting the test pattern data and the plurality of chip identification data responsive to collection thereof.

8. The method of claim 7, wherein generating the test pattern data comprises:
generating the test pattern data based on particular characteristics of the plurality of devices under test.

9. A method for testing a plurality of semiconductor devices, the method comprising:
receiving a plurality of chip identification data respectively corresponding to a plurality of devices under test; and
writing the plurality of chip identification data to corresponding ones of the plurality of devices under test in parallel.

10. The method of claim 9, further comprising:
reading the plurality of chip identification data in parallel prior to writing the plurality of chip identification data.

11. The method of claim 9, further comprising:
writing test pattern data to the plurality of devices under test in parallel.

12. The method of claim 11, further comprising the following prior to writing the test pattern data:
receiving input signal pattern data for the plurality of devices under test; and
transforming the input signal pattern data into logical signal pattern data,
wherein writing the test pattern data comprises writing the logical signal pattern data to the plurality of devices under test in parallel.

13. The method of claim 9, further comprising the following prior to receiving the plurality of chip identification data:
sequentially generating chip identification data for each of the plurality of devices under test to collect the plurality of chip identification data; and
transmitting the plurality of chip identification data responsive to collection of the chip identification data for each of the plurality of devices under test.

14. An apparatus for testing a plurality of semiconductor devices, comprising:
a controller configured to receive a plurality of chip identification data respectively corresponding to a plurality of devices under test; and
a writing unit coupled to the controller and configured to write the plurality of chip identification data to corresponding ones of the plurality of devices under test in parallel.

15. The apparatus of claim 14, further wherein the writing unit is further configured to read the plurality of chip identification data in parallel responsive to receipt thereof by the controller.

16. The apparatus of claim 14, further comprising:
an interface unit configured to provide a parallel connection between the writing unit and the plurality of devices under test.

17. The apparatus of claim 14, wherein the writing unit is configured to receive input signal pattern data for the plurality of devices under test from the controller, transform the input signal pattern data into logical signal pattern data, and write the logical signal pattern data to the plurality of devices under test in parallel.

18. The apparatus of claim 14, further comprising:
a programming unit configured to generate chip identification data for each of a plurality of devices under test, collect the chip identification data to provide the plurality of chip identification data respectively corresponding to the plurality of devices under test, and transmit the plurality of chip identification data for the plurality of devices under test to the controller responsive to collection of the plurality of chip identification data.

19. The apparatus of claim 18, wherein the programming unit is configured to generate test pattern data for the plurality of devices under test, and wherein the programming unit is further configured to transmit the test pattern data and the plurality of chip identification data to the controller responsive to collection of the plurality of chip identification data.

20. The apparatus of claim 19, wherein the writing unit is further configured to write the test pattern data and the plurality of chip identification data to the plurality of devices under test in parallel.
